(19) United States
(12) Patent Application Publication
(10) Pub. No.: US 2025/0140513 A1
(43) Pub. Date: May 1, 2025

(54) CHARGED PARTICLE BEAM DEVICE

(71) Applicant: HITACHI HIGH-TECH SCIENCE CORPORATION, Tokyo (JP)

(72) Inventors: Satoshi TOMIMATSU, Tokyo (JP); Tatsuya ASAHATA, Tokyo (JP); Makoto SATO, Tokyo (JP); Masato SUZUKI, Tokyo (JP)

(21) Appl. No.: 18/687,688

(22) PCT Filed: Sep. 1, 2021
(86) PCT No.: PCT/JP2021/032137

§ 371 Date: Feb. 28, 2024

(51) Int. Cl. H01J 37/20; H01J 37/22; H01J 37/30; H01J 37/317

(52) U.S. Cl. CPC H01J 37/20; H01J 37/222; H01J 37/3005; H01J 37/317; H01J 2237/022

(57) ABSTRACT

This charged particle beam device (10) comprises a focused ion beam irradiation optical system (14), an electron beam irradiation optics (15), a needle (18), a needle drive mechanism (19), a display device (21), and a computer (22). The computer (22) stores coordinate data for the needle drive mechanism (19) when the tip of the needle (18) matches a prescribed position in an image obtained by irradiating the needle (18) with a focused ion beam or an electron beam. The computer (22) controls the needle drive mechanism (19) and the focused ion beam irradiation optics (14) such that when the total amount of change in the coordinate data in a suitable period is at least a prescribed threshold, a process is executed for removing, by means of irradiation with the focused ion beam, at least a portion of a deposition film attached to the tip of the needle (18).

### CROSS REFERENCE

The present Application for Patent is a 371 national phase filing of International Patent Application No. PCT/JP2021/032137, by TOMIMATSU et al., entitled “CHARGED PARTICLE BEAM DEVICE,” filed Sep. 1, 2021, assigned to the assignee hereof, and expressly incorporated by reference herein.

### TECHNICAL FIELD

The present invention relates to a charged particle beam device.

### BACKGROUND ART

In the past, there is known a device that automatically performs sampling by picking a sample piece produced by irradiating a sample with a charged particle beam of electrons or ions from a sample and transferring the sample piece to a sample piece holder (see, for example, Patent Document 1).

### DOCUMENT OF RELATED ART

### Patent Document

Patent Document 1: Japanese Patent Application Publication No. 2016-50854

### DISCLOSURE

### Technical Field

In the conventional device described above, trimming to process the tip shape of a needle used for transportation of a sample piece into a predetermined shape is performed at an appropriate timing when repeatedly sampling a plurality of sample pieces. In the trimming, for cleaning to remove deposits such as a deposition film connecting a sample piece and the tip of a needle and for shaping the needle, a charged particle beam is applied to the deposition film according to a processing range set on the basis of the contour information of a needle template, for example.

However, when a contour line that makes the needle tip shape of a finite size is set as the template, it may not be possible to properly remove deposits such as a deposition film that grows outward from the tip of the needle. For example, when a deposit that grows axially outward from the tip of the needle remains, the needle cannot be properly made to approach the sample piece when connecting the needle to the sample piece, and the needle body will come into contact with an unsuitable part.

The present invention has been made in view of the above-mentioned circumstances, and it is an object to provide a charged particle beam device enabling the tip of a needle used for transferring a sample piece to be maintained in an appropriate predetermined shape.

### Technical Field

In order to solve the above problem, according to the present invention, there is provided a charged particle beam device for automatically producing a sample piece from a sample. The charged particle beam device includes: a charged particle beam irradiation optics applying a charged particle beam; a sample stage on which a sample is loaded and moved; a sample piece transfer means for holding and transporting a sample piece to be separated and extracted from the sample; a holder securing stand holding the sample piece holder to which the sample piece is transferred; a gas supply unit supplying gas to form a deposition film by irradiation with the charged particle beam; and a computer storing coordinate data indicating a real-space position of the sample piece transfer means in case a tip of the sample piece transfer means is present within a predetermined tolerance range from a predetermined position in an image obtained by irradiating the sample piece transfer means with the charged particle beam in a state in which the sample piece is not held and controlling the sample piece transfer means and the charged particle beam irradiation optics to carry out processing to remove at least part of the deposition film attached to the tip of the sample piece transfer means by irradiation with the charged particle beam in case an amount of change in the coordinate data for a suitable period of time is equal to or greater than a predetermined threshold value.

In the configuration, when separating the sample piece from the sample piece transfer means that holds the sample piece, the computer may set a processing area according to an amount of change in the coordinate data in the image obtained by the irradiation with the charged particle beam, and may remove at least part of the deposition film attached to the tip of the sample piece transfer means by irradiating the processing area with the charged particle beam.

In the configuration, the computer may carry out the processing so that the amount of change in the coordinate data from at least the tip of the sample piece transfer means in an axially outward direction parallel to a central axis of the sample piece transfer means becomes less than the predetermined threshold value.

### Advantageous Effects

According to the present invention, due to the inclusion of the computer that irradiates the deposition film on the tip of the sample piece transfer means with a charged particle beam when the amount of change in the coordinate data of the sample piece transfer means memorizing when the externally observed tip of the sample piece transfer means matches a predetermined position, is a predetermined threshold or more, the tip shape of the sample piece transfer means can be maintained as an appropriate predetermined shape.

### DESCRIPTION OF RELATED ART

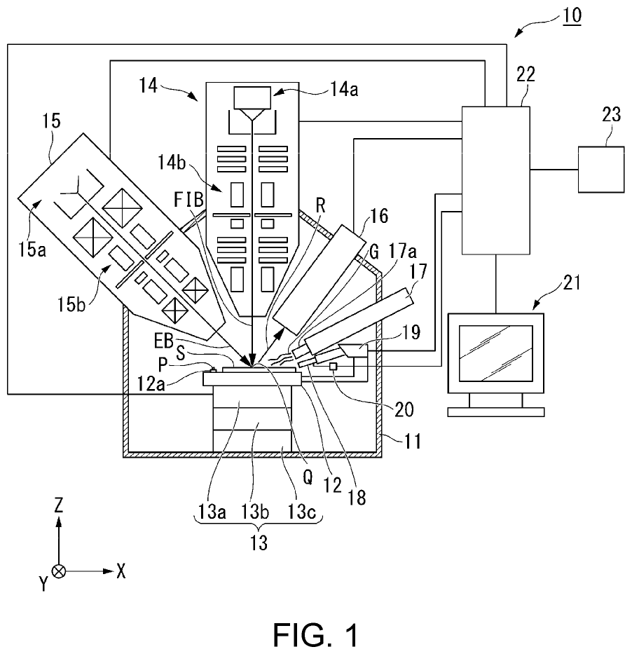

FIG. 1 is a configuration view of a charged particle beam device according to one embodiment of the present invention.

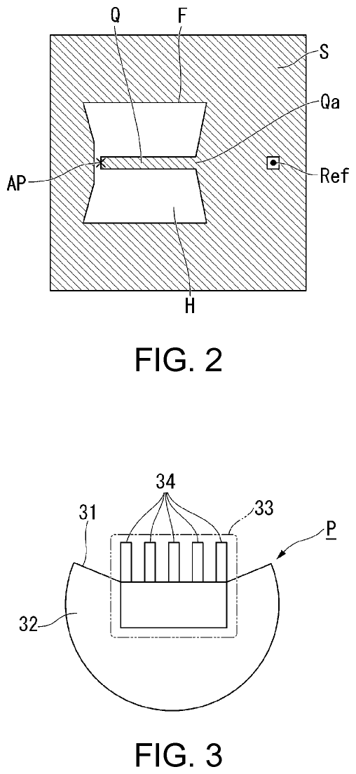

FIG. 2 is a plan view illustrating a sample piece formed in a sample in the charged particle beam device according to the embodiment of the present invention.

FIG. 3 is a plane view illustrating a sample piece holder of the charged particle beam device according to the embodiment of the present invention.

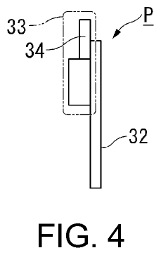

FIG. 4 is a side elevation view illustrating the sample piece holder of the charged particle beam device according to the embodiment of the present invention.

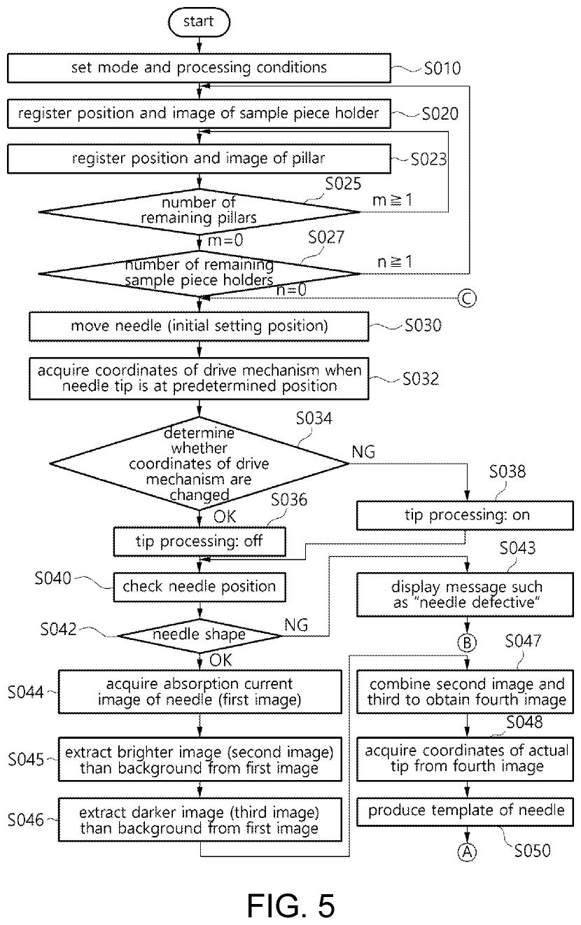

FIG. 5 is a flowchart illustrating the operation of the charged particle beam device according to the embodiment of the present invention and specifically a flow chart illustrating an initial setting process.

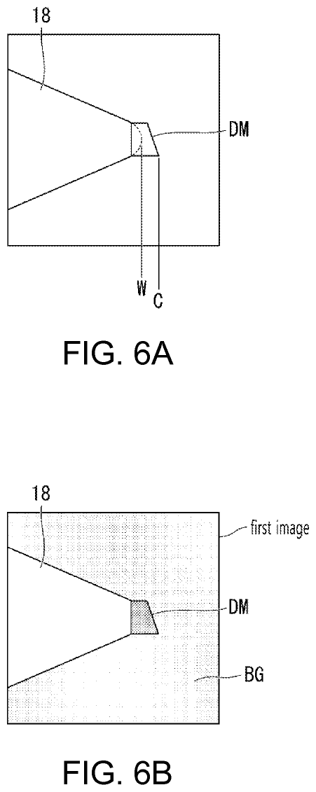

FIG. 6A and FIG. 6B show schematic diagrams for description of the actual tip of the needle repeatedly used in the charged particle beam device according to the embodiment of the present invention, in which FIG. 6A is a schematic view for description of the actual needle tip and FIG. 6B is a schematic view for description of a first image obtained with an absorption current signal.

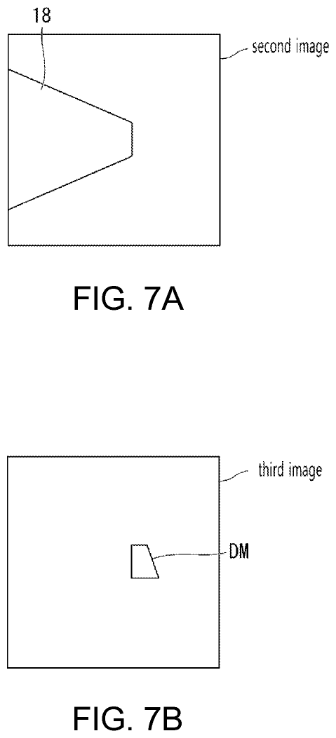

FIG. 7A and FIG. 7B illustrate schematic diagrams of secondary electron images upon application of an electron beam to the needle tip in the charged particle beam device according to the embodiment of the present invention, in which FIG. 7A is a schematic view illustrating a second image obtained by extracting the area brighter than the background and FIG. 7B is a schematic view illustrating a third image obtained by extracting the area darker than the background.

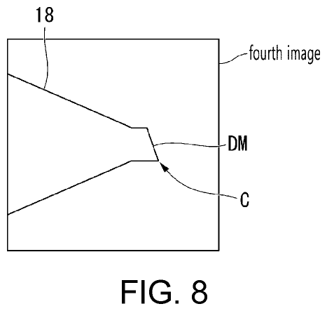

FIG. 8 is a schematic view for description of a fourth image synthesized from the second and third images shown in FIGS. 7A and 7B.

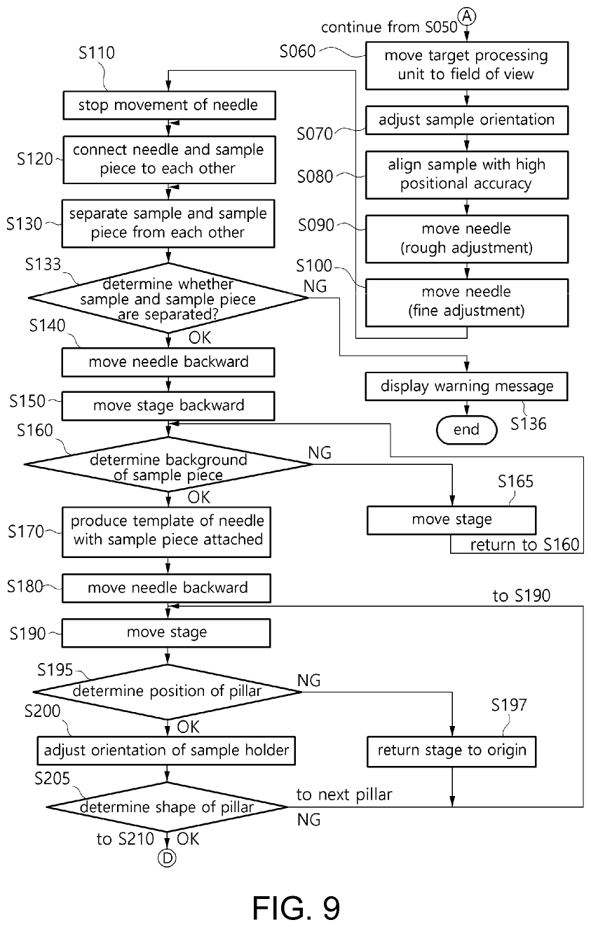

FIG. 9 is a flowchart illustrating a sample pick-up process included in the flowchart illustrating the operation of the charged particle beam device according to the embodiment of the present invention.

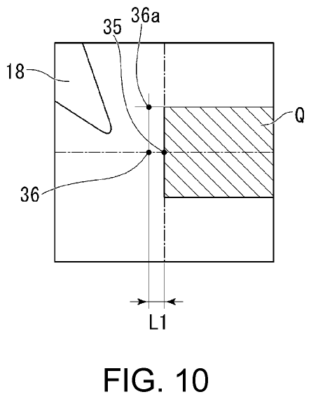

FIG. 10 is a schematic view illustrating a needle stop position when a needle is moved to approach a sample piece in the charged particle beam device according to the embodiment of the present invention.

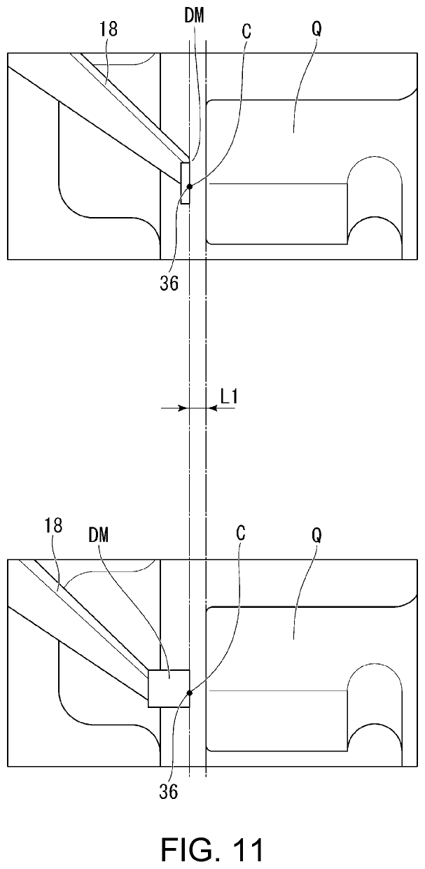

FIG. 11 is a view schematically illustrating an example of a positional relationship between the needle and the sample piece depending on the size of a carbon deposition film attached to a needle tip in one embodiment of the present invention.

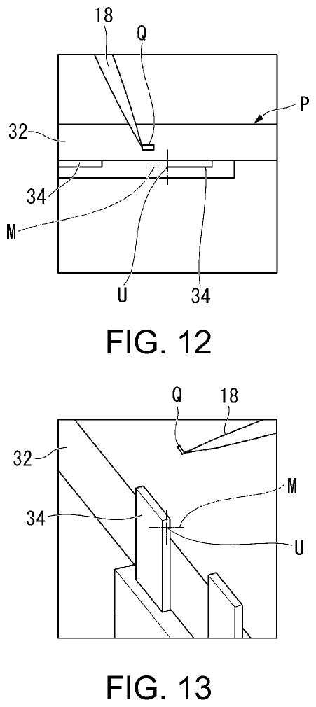

FIG. 12 is a view illustrating a sample piece attachment position of a columnar section in an image obtained by using a focused ion beam of the charged particle beam device according to the embodiment of the present invention.

FIG. 13 is a view illustrating a sample piece attachment position of a columnar section in an image obtained by using an electron beam of the charged particle beam device according to the embodiment of the present invention.

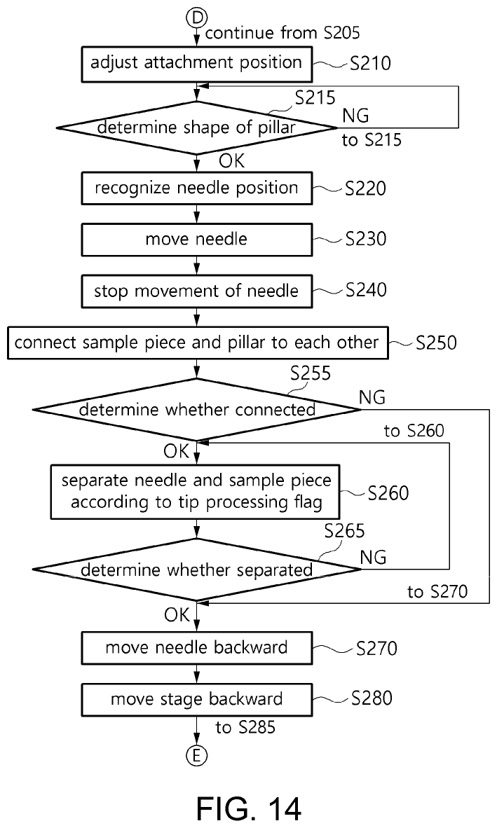

FIG. 14 is a flowchart illustrating a sample piece mounting process included in a flowchart illustrating the operation of the charged particle beam device according to the embodiment of the present invention.

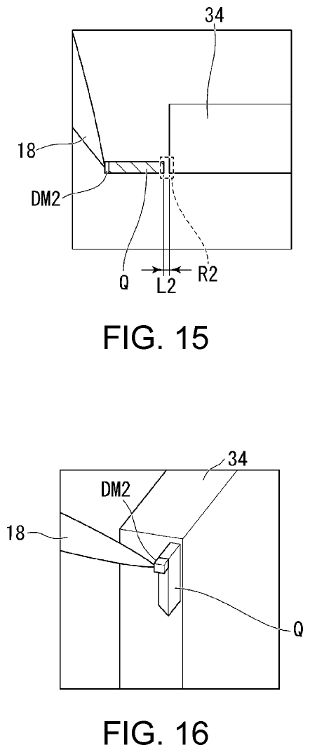

FIG. 15 is a view illustrating a needle whose movement is stopped near the sample piece attachment position of the columnar section in an image obtained by using a focused ion beam of the charged particle beam device according to the embodiment of the present invention.

FIG. 16 is a view illustrating a needle whose movement is stopped near the sample piece attachment position of the columnar section in an image obtained by using an electron beam of the charged particle beam device according to the embodiment of the present invention.

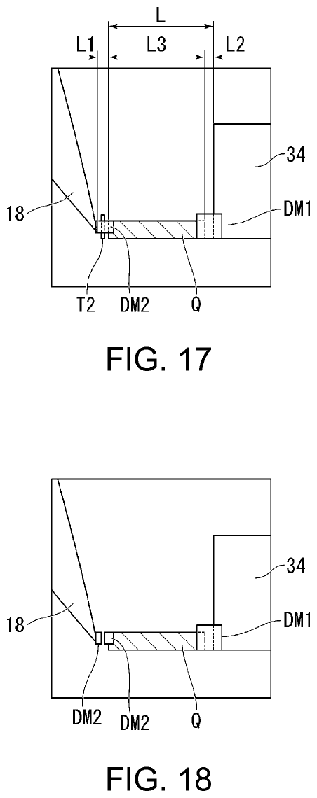

FIG. 17 is a view illustrating a processing range for connecting a sample piece connected to a needle, to a sample stand in an image obtained by using a focused ion beam of the charged particle beam device according to the embodiment of the present invention.

FIG. 18 is a view illustrating a cut processing position for cutting a deposition film that connects a needle to a sample piece, in an image obtained by using a focused ion beam of the charged particle beam device according to the embodiment of the present invention.

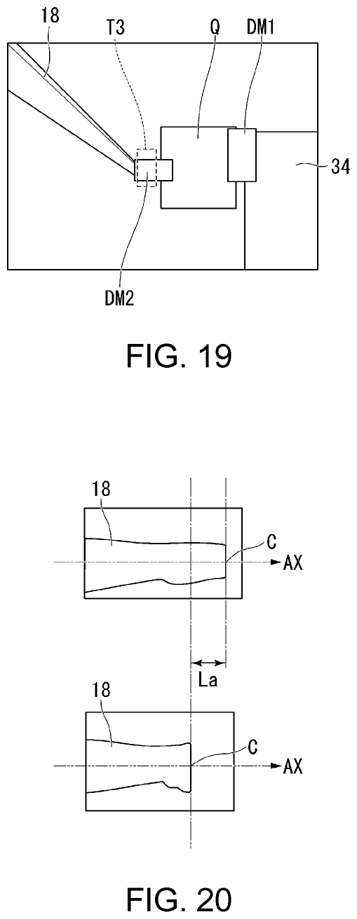

FIG. 19 is a view illustrating a processing range for connecting a sample piece connected to a needle, to a sample stand in an image obtained by using a focused ion beam of the charged particle beam device according to the embodiment of the present invention.

FIG. 20 is a view illustrating a needle tip portion before and after predetermined tip processing performed with the use of a focused ion beam of the charged particle beam device according to the embodiment of the present invention.

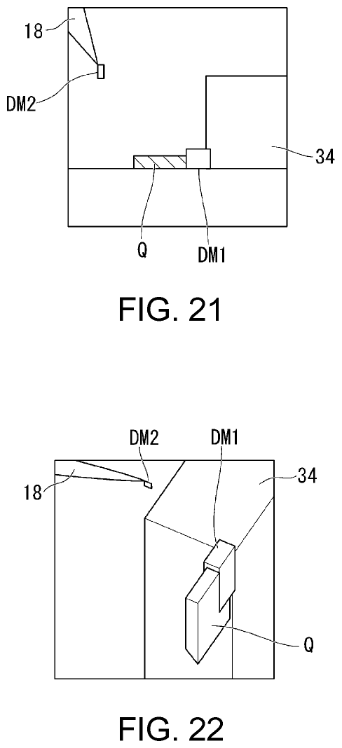

FIG. 21 is a view illustrating a state in which a needle has retreated in image data obtained by using a focused ion beam of the charged particle beam device according to the embodiment of the present invention.

FIG. 22 is a view illustrating a state in which a needle has retreated in an image data obtained by using an electron beam of the charged particle beam device according to the embodiment of the present invention.

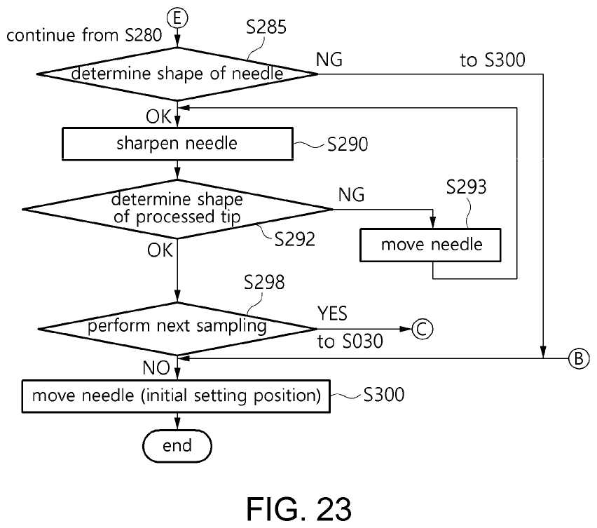

FIG. 23 is a flowchart illustrating a needle trimming process included in the flowchart illustrating the operation of the charged particle beam device according to the embodiment of the present invention.

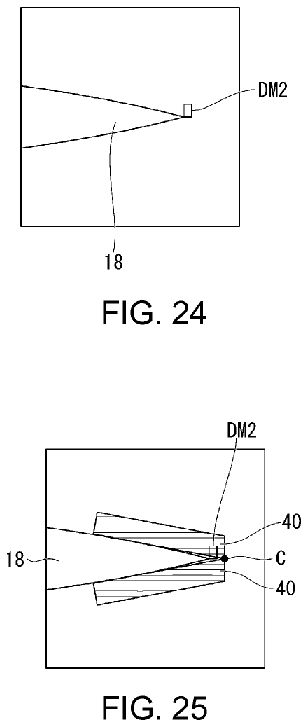

FIG. 24 is a view illustrating a needle tip state in image data obtained with the use of a focused ion beam of the charged particle beam device according to the embodiment of the present invention.

FIG. 25 is a view in which the processing range for milling is overlaid on the image of FIG. 24.

### BEST MODE

Hereinafter a charged particle beam device capable of automatically producing a sample piece, according to one embodiment of the present invention, will be described with reference to the accompanying drawings.

FIG. 1 is a configuration view of a charged particle beam device 10 according to one embodiment of the present invention. Referring to FIG. 1, the charged particle beam device 10 according to the embodiment of the present invention includes a sample chamber 11 whose interior can be maintained in a vacuum state, a stage 12 that can fix a sample S and a sample piece holder P in the sample chamber 11, and a stage drive mechanism 13 that drives the stage 12. The charged particle beam device 10 is equipped with a focused ion beam (FIB) irradiation optics 14 that directs a focused ion beam (FIB) at an irradiation target object within a predetermined irradiation region (that is, scanning region) inside the sample chamber 11. The charged particle beam device 10 is equipped with an electron beam irradiation optics 15 that directs an electron beam (EB) at an irradiation target object within a predetermined irradiation region inside the sample chamber 11. The charged particle beam device 10 is equipped with a detector 16 that detects secondary charged particles (such as secondary electrons and secondary ions) generated from the irradiation target object irradiated with the focused ion beam or the electron beam. The charged particle beam device 10 is equipped with a gas supply unit 17 that supplies gas to the surface of the irradiation target object. The gas supply unit 17 is specifically a nozzle 17a, etc. The charged particle beam device 10 is equipped with: a needle 18 that takes a minute sample piece Q from the sample S fixed on the stage 12, holds the sample piece Q, and transfers the sample piece Q to the sample piece holder P; a needle drive mechanism 19 that drives the needle 18 to transfer the sample piece Q; and an absorption current detector 20 that detects the charged particle beam inflow current (also referred to as absorption current) flowing to the needle 18. The signal of the inflow current is transmitted to a computer and is imaged in the computer.

The needle 18 and the needle drive mechanism 19 are collectively referred to as a sample piece transfer means. The charged particle beam device 10 is equipped with a display device 21 that displays image data and other data on the basis of the secondary charged particles R detected by the detector 16, a computer 22, and an input device 23.

The irradiation target objects of the focused ion beam irradiation optics 14 and electron beam irradiation optics 15 are the sample S fixed on the stage 12, the sample piece Q, and the needle 18 and sample piece holder P disposed in the irradiation region.

The charged particle beam device 10 according to the embodiment can perform imaging of the irradiated portion, various types of processing (such as drilling and trimming processes) based on sputtering, deposition film formation, etc., by irradiating the irradiation target object with the focused ion beam while scanning the surface of the irradiation target object. The charged particle beam device 10 can perform processing on the sample S to form sample pieces Q (for example, lamella samples and needle-shaped samples) for transmission electron microscopic observation and to form analytical sample pieces for electron beam analysis. The charged particle beam device 10 can perform processing on a sample piece transferred to the sample piece holder P into a thin film with the desired thickness suitable for transmission electron microscopic observation. The Charged particle beam device 10 enables observation of the surface of the irradiation target object by applying the focused ion beam or electron beam to the surface of the irradiation target object such as the sample piece Q and the needle 18 while scanning the surface of the irradiation target object.

The absorption current detector 20 is equipped with a preamplifier that amplifies the inflow current into the needle and sends the amplified current to the computer 22. The needle inflow current detected by the absorption current detector 20 and the signal synchronized with the scanning of the charged particle beam enable the display device 21 to display an absorption current image of the needle shape so that the needle shape and the needle tip position can be identified.

FIG. 2 is a plan view illustrating the sample piece Q that is formed by applying the focused ion beam to the surface of the sample S (hatched portion) and is not yet picked up from the sample S, in the charged particle beam device according to the embodiment of the present invention. Reference symbol F denotes the processing range of the focused ion beam, that is, the scanning range of the focused ion beam. The inside of the range (white portion) indicates the processing region H, which is etched by sputtering based on the focused ion beam irradiation. Reference sign Ref denotes a reference mark (reference point) that indicates the position at which the sample piece Q is to be formed (that is, a portion that is not etched but remains). For example, a micro hole is formed in a deposition film to be described below by the focused ion beam. The deposition film is used to roughly know the approximate position of the sample piece Q, and the micro hole is used for precise positioning. In the sample S, the sample piece Q is etched so that the periphery of the side and bottom sides of the sample piece Q are shaved and removed while a support portion Qa connected to the sample S is left such that the sample piece Q is cantilevered to the sample S by the support portion Qa.

The sample chamber 11 can be evacuated by an air exhauster (not illustrated) until the interior of the sample chamber 11 reaches the desired reduced pressure and configured to maintain the desired reduced pressure.

The stage 12 holds the sample S. The stage 12 is equipped with a holder securing stand 12a that holds the sample piece holder P. This holder securing stand 12a may be structured to support multiple sample piece holders P.

FIG. 3 is a plan view of the sample piece holder P, and FIG. 4 is a side elevation view of the sample piece holder P. The sample piece holder P is equipped with a substantially semicircular plate-shaped base 32 with a notch 31 and a sample stand 33 that is fixed to the notch 31. The base 32 is formed from a circular plate made of, for example, a metal. The sample stand 33 is formed from a silicon wafer, for example, by a semiconductor manufacturing process, and is affixed to the notch 31 by a conductive adhesive. The sample stand 33 is comb-shaped and is provided with a plurality of protruding columnar sections 34 (hereinafter, also referred to as pillars) spaced from each. The sample pieces Q are transferred to the pillars 34.

It is preferable that the base 32 is shaped to be mountable on the stage 12 to be introduced into the subsequent-stage transmission electron microscope, and shaped such that all of the sample pieces Q mounted on the sample stand 33 can be placed within the movable range of the stage 12.

The stage drive mechanism 13 is housed inside the sample chamber 11 in a state of being connected to the stage 12, and displaces the stage 12 with respect to a predetermined axis in response to a control signal output from the computer 22. The stage drive mechanism 13 is equipped with a moving mechanism 13a that moves the stage 12 along at least the X and Y axes that are parallel to the horizontal plane and are orthogonal to each other, and moves the stage 12 along the Z axis that is orthogonal to each of the X axis and the Y axis. The stage drive mechanism 13 includes a tilt mechanism 13b that tilts the stage 12 around the X or Y axis and a rotation mechanism 13c that rotates the stage 12 around the Z axis.

The focused ion beam irradiation optics 14 is fixed to the sample chamber 11, with the beam emitting portion (not illustrated) thereof facing the stage 12 from above the stage 12 in the vertical direction within the irradiation region, and with the optical axis thereof being parallel to the vertical direction. This arrangement makes it possible to perpendicularly apply a focused ion beam to the irradiation target objects such as the sample S, the sample piece Q, and the needle 18 disposed within the irradiation region directly from above the irradiation target objects. The charged particle beam device 10 may be equipped with other ion beam irradiation optics instead of the focused ion beam irradiation optics 14 described above. The ion beam irradiation optics is not limited to the optics that forms a focused beam as described above. The ion beam irradiation optics may be, for example, a projection-type ion beam irradiation optics in which a stencil mask with a shaped aperture is installed to form a shaped beam with the shape of the aperture of the stencil mask. The focused ion beam irradiation optics 14 is equipped with an ion source 14a that generates ions and an ion optics 14b that focuses and deflects the ions extracted from the ion source 14a. The ion source 14a and the ion optics 14b are controlled according to control signals output from the computer 22, and the irradiation position and irradiation conditions of the focused ion beam are controlled by the computer 22. The ion source 14a is, for example, a liquid metal ion source using liquid gallium or the like, a plasma ion source, or a gas field emission ion source. The ion optics 14b is equipped with, for example, a first electrostatic lens, such as a condenser lens, an electrostatic deflector, and a second electrostatic lens, such as an objective lens.

The electron beam irradiation optics 15 is fixed to the sample chamber 11, with the beam emitting portion (not illustrated) thereof facing the stage 12 in an oblique direction inclined by a predetermined angle (for example, 60°) with respect to the perpendicular direction of the stage 12 within the irradiation region inside the sample chamber 11, and with the optical axis thereof being parallel to the oblique direction. This arrangement makes it possible to apply an electron beam to the irradiation target objects such as the sample S, the sample piece Q, and the needle 18 fixed to the stage 12 and disposed within the irradiation region from above the irradiation target objects in the oblique direction.

The electron beam irradiation optics 15 is equipped with an electron source 15a that generates electrons and an electron optics 15b that focuses and deflects the electrons emitted from the electron source 15a. The ion source 15a and the ion optics 15b are controlled according to control signals output from the computer 22, and the irradiation position and irradiation conditions of the electron beam are controlled by the computer 22. The electron optics 15b is equipped with, for example, an electromagnetic lens and a deflector.

The positions of the electron beam irradiation optics 15 and the focused ion beam irradiation optics 14 may be switched, so that the electron beam irradiation optics 15 may be positioned in the vertical direction and the focused ion beam irradiation optics 14 may be positioned in the oblique direction inclined by the predetermined angle with respect to the vertical direction.

The detector 16 detects the intensity of secondary charged particles (secondary electrons and secondary ions) R (i.e., the amount of secondary charged particles) emitted from the irradiation target when the focused ion beam or electron beam is applied to the irradiation target such as the sample S and needle 18, and outputs information of the detected amount of secondary charged particles R. The detector 16 is disposed inside the sample chamber 11 at a position where the amount of secondary charged particles R can be detected, for example, at a position obliquely above the irradiation target such as the sample S in the irradiation region. The detector 16 is fixed to the sample chamber 11.

The gas supply unit 17 is fixed to the sample chamber 11 and has a gas ejection unit (also referred to as a nozzle) inside the sample chamber 11, and is arranged to face the stage 12. The gas supply unit 17 can supply the sample S with an etching gas to selectively promote etching of the sample S according to the material of the sample S when the sample S is etched by the focused ion beam and can supply a deposition gas to form a metal or insulator deposition film on the surface of the sample S. Depending on the supplied gas, etching and deposition can also be performed by electron beam irradiation.

The needle drive mechanism 19 is housed inside the sample chamber 11 in a state of being mounted with the needle 18, and displaces the needle 18 according to a control signal output from the computer 22. The needle drive mechanism 19 is integrated with the stage 12. For example, when the stage 12 is rotated around the tilt axis (i.e., X or Y axis) by the tilt mechanism 13b, the needle drive mechanism 19 and the stage 12 move together. The needle drive mechanism 19 has a moving mechanism (not illustrated) that moves the needle 18 parallel along each of the three-dimensional coordinate axes and a rotation mechanism (not illustrated) that rotates the needle 18 around the central axis of the needle 18. The three-dimensional coordinate axes are independent of the triaxial rectangular coordinate system of the sample stage. The three-dimensional coordinate axes are a triaxial rectangular coordinate system with two-dimensional coordinate axes parallel to the surface of the stage 12. When the surface of the stage 12 is in a tilted or rotated state, this coordinate system will be tilted and rotated.

The computer 22 controls at least the stage drive mechanism 13, the focused ion beam irradiation optics 14, the electron beam irradiation optics 15, the gas supply unit 17, and the needle drive mechanism 19.

The computer 22 is disposed outside the sample chamber 11 and is connected to a display device 21 and an input device 23 such as a mouse or keyboard that outputs signals in response to the operator's input operations.

The computer 22 controls the overall operation of the charged particle beam device 10 by, for example, signals output from the input device 23 or signals generated by a predetermined automatic operation control process.

The computer 22 converts the detected amount of secondary charged particles R detected by the detector 16 while scanning the irradiation position of the charged particle beam into a brightness signal on the irradiation position, and generates image data showing the shape of the irradiation target object on the basis of the two-dimensional positional distribution of the detected amount of secondary charged particles R. In an absorption current imaging mode, the computer 22 detects the absorbed current flowing to the needle 18 while scanning the irradiation position of the charged particle beam, thereby generating absorption current image data that indicates the shape of the needle 18 in the form of the two-dimensional positional distribution of the absorbed current (absorption current image). The computer 22 displays a screen on the display unit 21 for allowing operations such as zooming in, zooming out, moving, and rotating each image data, as well as each piece of the generated image data. The computer 22 displays a screen on display unit 21 for allowing various settings such as mode selection and processing settings in an automatic sequence control process.

The charged particle beam device 10 according to the embodiment of the present invention has the above configuration, and the operation of the charged particle beam device 10 will be described below.

Hereinafter, the operation of automatic sampling performed by the computer 22, that is, the operation of automatically transferring the sample piece Q formed by processing the sample S with the charged particle beam (focused ion beam) to the sample piece holder P, will be roughly divided into an initial setup process, a sample piece pickup process, and a sample piece mounting process, which will be described sequentially.

### Initial Setup Process

FIG. 5 is a flowchart illustrating the flow of the initial setup process among the automatic sampling operations of the charged particle beam device 10 according to the embodiment of the present invention. First, at the start of the automatic sequence, the computer 22 performs mode selection, such as whether or not to use a posture control mode described below, in response to the operator's input, performs setting of observation conditions for template matching and processing conditions (processing position, size, number of pieces, etc.), and checks a needle tip shape (step S010).

Next, the computer 22 creates a template for the columnar sections 34 (steps S020 through S027). In this template creation step, the computer 22 first performs a position registration process for the sample piece holder P that is placed on the holder securing stand 12a of the stage 12 by the operator (step S020). The computer 22 acquires the stage coordinates and creates a template for each of the columnar sections, stores the coordinates and the template as a set, and uses the stored data later at the time of determining the shape of the columnar sections 34 through template matching (superposition of a template and an image).

With the use of the template that is preliminarily created from the designed shape (CAD information) of the sample stand 33, the computer 22 extracts the positions of the respective columnar sections 34 that make up the sample stand 33, from each piece of the image data generated by irradiating the irradiation target objection with each of the charged particle beams (the focused ion beam and the electron beam). Next, the computer 22 registers (stores) the position coordinates and images of each extracted columnar section 34 as the mounting position of the sample piece Q (step S023). In this case, when the image of each of the columnar sections 34 is defective when compared with a pre-prepared design drawing or CAD drawing of the columnar section or an image of a standard one of the columnar sections 34, the computer 22 also stores both of the coordinate position and image of that columnar section to be defective along with the coordinate position and the image of that columnar section.

Next, it is determined whether there are columnar sections 34 to be registered in the sample piece holder P that is currently undergoing the registration process (step S025). When the result of the determination is “YES”, that is, when the number m of the remaining columnar sections 34 to be registered is 1 or more, the process returns to step S023 described above, and steps S023 and S025 are repeated until the number m of the remaining columnar sections 34 becomes zero (0). On the other hand, when the result of the determination is “NO”, that is, when the number m of the remaining columnar sections 34 to be registered is zero, the process proceeds to step S027.

When the holder securing stand 12a is provided with multiple sample piece holders P, the position coordinates of each of the sample piece holders P and the image data of the corresponding sample piece holder P are recorded together along with the code number for each of the sample piece holders P. Furthermore, the position coordinates of each of the columnar sections 34 of each of the sample piece holders P, the corresponding code number, and the corresponding image data are stored together (registration process). The computer 22 may repeatedly perform the position registration process by a certain number of times corresponding to the number of sample pieces Q that is to undergo automatic sampling.

Then, the computer 22 determines whether there is a remaining sample piece holder P to be registered (step S027). When the result of the determination is “YES”, that is, when the number n of the remaining sample piece holders P to be registered is 1 or more, the process returns to step S020 described above, and steps S020 and S027 are repeated until the number n of the remaining sample piece holders P becomes zero (0). On the other hand, when the result of the determination is “NO”, that is, when the number n of the remaining sample piece holders P to be registered is zero, the process proceeds to step S030.

In this position registration process (steps S020 and S023), when the sample piece holder P itself or the columnar section 34 is deformed or damaged, and the sample piece Q is in a state of not being mounted, the message “unavailable” (a notation indicating that the sample piece Q is not mounted) is registered along with the position coordinates, image data, and code number. This allows the computer 22 to skip the “unavailable” sample piece holder P or columnar section 34 and to move the next normal sample piece holder P or columnar section 34 into the observation field of view when transferring the sample piece Q.

Next, the computer 22 creates a template for the needle 18 (steps S030 through S050). The template is used for image matching when precisely approaching the needle 18 to the sample piece Q, as described below.

In this template creation process, the computer 22 first controls the stage drive mechanism 13 to move the stage 12. The computer 22 then controls the needle drive mechanism 19 to move the needle 18 to the initial setting position (step S030). The initial setting position is a predetermined position at which substantially the same point can be irradiated with the focused ion beam and the electron beam. The position is the point where both beams meet in focus (coincidence point). At the position, no complicated structure such as the sample S, which can be mistaken for the needle 18, is not present in the background of the needle 18, due to the stage movement performed immediately before. This coincidence point is a position where the same object can be observed from different angles by focused ion beam irradiation and electron beam irradiation.

When the computer 22 controls the needle drive mechanism 19 to move the needle 18 to the initial setting position, in the case where the tip of the needle 18 (i.e., the apparent tip) is at a predetermined position (for example, the initial setting position such as the coincidence point) in image data of each of the SIM and SEM images, the coordinate data of the needle drive mechanism 19 in a state in which the tip of the needle 18 is present within a predetermined tolerance range from the predetermined position (step S032) can be obtained. The SIM image is an image generated by focused ion beam irradiation, and the SEM image is an image generated by electron beam irradiation. The coordinate data is data of the three-dimensional coordinates of the position of the needle 18 in real space, which are recognized by the needle drive mechanism 19. For example, the computer 22 recognizes the tip of the needle 18 in each of the SIM and SEM images through appropriate image processing, and ascertains the occurrence of an event in which the tip of the needle 18 coincides with the coincidence point in each image. The computer 22 stores the coordinate data obtained when the tip of the needle 18 coincides with the coincidence point in each image.

Next, the computer 22 determines changes in coordinate data from the history of coordinate data obtained in step S032 (step S034). For example, the computer 22 determines whether the cumulative value of the difference between the previous value and the current value of the coordinate data, that is, the total change in the coordinate data for a suitable period of time, is equal to or greater than a predetermined threshold value. The suitable period of time is, for example, a period of time that is reset each time specified tip processing is performed when the tip processing flag described below is set to ON, and is a period of time from the most recent tip processing to the present time. The predetermined threshold is, for example, a threshold value for the amount of change in the coordinate data in at least an axially outward direction from the tip of the needle, which is parallel to the central axis of the needle 18. The predetermined threshold is, for example, about 0.5 μm.

Next, when the total change in coordinate data is less than a predetermined threshold (step S034; OK), the computer 22 makes the process proceed from step S034 to step S036. Next, the computer 22 sets the tip processing flag to OFF (step S036).

On the other hand, when the total change in coordinate data is greater than the predetermined threshold (step S034; NG), the computer 22 makes the process proceed from step S034 to step S038. Next, the computer 22 sets the tip processing flag to ON (step S038).

The tip processing flag indicates whether or not the prescribed tip processing is required to reduce the total change in the coordinate data to less than a predetermined threshold by removing deposits such as a deposition film on the tip of the needle 18 by irradiating the deposition film with a focused ion beam.

Next, the computer 22 recognizes the position of the needle 18 by electron beam irradiation in an absorption image mode (step S040).

In the absorption current imaging mode, the computer 22 detects the absorption current flowing through the needle 18 by scanning the needle 18 with the electron beam, and generates absorption current image data. In this case, the needle 18 can be recognized without being affected by the background image because the absorption current image has no background that can be misidentified as the needle 18. The computer 22 acquires absorption current image data by electron beam irradiation.

Here, the computer 22 determines the shape of the needle 18 (step S042).

When the tip shape of the needle 18 is not in a condition to retain the sample piece Q due to deformation or damage (step S042; NG), the process jumps from step S043 to the NO side of step S298 in FIG. 36. That is, the automatic sampling operation ends without performing all the steps subsequent to step S050 When the needle shape is determined to be defective in step S042, the message “needle defective” or the like is displayed on the display device 21 (step S043) to warn the operator. The needles 18 determined to be defective may be replaced with new needles 18. Alternatively, when the defect is minor, the defective needle tips are irradiated with a focused ion beam so as to be sharpened.

In step S042, when the needle 18 has a predetermined normal shape, the process proceeds to the subsequent step S044.

Here, the condition of the needle tip will be described.

FIG. 6A is an enlarged schematic view of a needle tip, in a state in which residue of a carbon deposition film DM is attached to the tip of the needle (tungsten needle) 18. Since the needle 18 is used for a number of repeated sampling operations to prevent the needle tip from being deformed by the focused ion beam irradiation, the tip of the needle 18 is covered with residue of the carbon deposition film DM that held the sample piece Q. With repeated sampling, this residue of the carbon deposition film DM gradually becomes larger and protrudes slightly beyond the tip apex of the tungsten needle. Therefore, the true tip coordinate of the needle 18 is not the tip W of the original tungsten that makes up the needle 18 but is the tip C of the residue of the carbon deposition film DM. As described above, the true needle tip cannot be identified because the carbon deposition film DM attached to the needle tip cannot be identified in the absorption current image. However, the absorption current image is suitable as a template image used for pattern matching with a template.

FIG. 6B is a schematic view of an absorption current image of a needle tip to which a carbon deposition film DM is attached. Even though there is a complex pattern in the background, the needle 18 can be clearly recognized without being affected by the pattern in the background. Since an electron beam signal applied to the background is not reflected on the image, the background appears in a uniform gray tone indicating a noise level. On the other hand, the carbon deposition film DM appears slightly darker than the gray tone of the background, and the tip of the carbon deposition film DM cannot be clearly identified in the absorption current image. Therefore, the coordinates of the true tip of the needle 18 are obtained from the coordinates of the tip of the carbon deposition film DM (i.e., tip of the residue) C as described below. Herein, the image shown in FIG. 6B will be referred to as a first image.

The process of acquiring the absorption current image (first image) of the needle 18 is step S044.

Next, the first image shown in FIG. 6B is subjected to image processing, so that regions brighter than the background are extracted (step S045).

FIG. 7A is a schematic view of the brighter region than the background, the region being extracted from the first image shown in FIG. 6B by performing image processing on the first image. An image in which the area (part of the needle 18) brighter than the background is emphasized is obtained, and this image is referred to here as a second image. The second image is stored in the computer.

Next, the regions darker than the background are extracted from the first image shown in FIG. 6B (step S046).

FIG. 7B is a schematic view of the darker region than the background, the region being extracted from the first image shown in FIG. 6B by performing image processing on the first image. Only the carbon deposition film DM at the needle tip is extracted and displayed. The image that demonstrates the region darker than the background is referred to as a third image, and the third image is stored in the computer 22.

Next, the second and third images stored in the computer 22 are combined (step S047).

FIG. 8 is a schematic view of a displayed image after image synthesis. However, for ease of viewing in the image, only the outline of the area of the needle 18 in the second image and the outline of the area of the carbon deposition film DM in the third image are represented as line drawings. The background and all the other parts except for the periphery of the needle 18 and carbon deposition film DM are displayed transparent. Alternatively, only the background may be displayed transparent, and the needle 18 and carbon deposition film DM may be displayed in the same color or tone. The synthesized image is referred to as a fourth image, and the fourth image is stored in the computer. The fourth image is produced by processing the first image, for example, adjusting the contrast and enhancing the contours. Therefore, when the first image and the fourth image are compared, the needle shapes are the same in both of the images, the contours are clearer in the fourth image, and the tip of the carbon deposition membrane DM is more clearly identified in the fourth image than in the first image.

Next, from the fourth image, the tip of the carbon deposition film DM, i.e., the true tip coordinates of the needle 18 with the carbon deposition film DM deposited at the needle can be obtained (step S048).

The fourth image is retrieved from the computer 22 and is displayed, and the true tip coordinates of the needle 18 are obtained. The point C (tip of the residue) that sticks out the most in the axial direction of the needle 18 is the true needle tip, and the point C is automatically determined by image recognition. The tip coordinates are stored in the computer 22.

Next, to further improve the accuracy of template matching, the following is performed: an absorption current image of the needle tip in the same observation field of view as in step S044 is obtained as a reference image: a template image is obtained by extracting a region including the needle from reference image, based on the needle tip coordinates obtained in step S048; and the template image is stored in the computer 22 in association with the reference coordinates of the needle tip (needle tip coordinates) obtained in step S048 (step S050).

Next, the computer 22 performs the process described blow to bring the needle 18 closer to the sample piece Q.

The process (S020 to S027) of creating the template for the columnar section 34 and the process (S030 to S050) of creating the template for the needle 18 may be performed in reverse order. However, when the process (S030 to S050) of creating the template for the needle 18 precedes, the flow C returning from step S298 described below is also changed.

### Sample Piece Pickup Process

FIG. 9 is a flowchart illustrating the process of picking the sample piece Q from the sample S during the automatic sampling operation performed by the charged particle beam device 10 according to the embodiment of the present invention. Here, the picking refers to the separation and removal of the sample piece Q from the sample S by processing with a focused ion beam or by needling.

First, the computer 22 controls the stage drive mechanism 13 to move the stage 12 so that the target sample piece Q enters the field of view of the charged particle beam. The position coordinates of the target reference mark Ref may be used to operate the stage drive mechanism 13. With the use of the recognized reference mark Ref, the computer 22 recognizes the position of the sample piece Q on the basis of the relative positional relationship between the known reference mark Ref and the sample piece Q, and moves the stage so that the sample piece Q enters the observation field of view (step S060).

Next, the computer 22 drives the stage 12 by using the stage drive mechanism 13 to rotate the stage 12 around the Z axis by an angle corresponding to the posture control mode so that the sample piece Q can be oriented in a predetermined posture (for example, a posture suitable for removal by the needle 18) (step S070).

Next, the computer 22 recognizes the reference mark Ref using the image data of the charged particle beam, recognizes the position of the sample piece Q with reference to the relative positional relationship between the known reference mark Ref and the sample piece Q, and performs alignment of the sample piece Q (step S080). Next, the computer 22 performs the process described blow to brining the needle 18 to closer to the sample piece Q.

The computer 22 then executes a needle transferring operation (rough adjustment) in which the needle drive mechanism 19 moves the needle 18 (step S090). The computer 22 recognizes the reference mark Ref (see FIG. 2 above) using the data of the images obtained by irradiating the sample S with the focused ion beam and the electron beam, respectively. The computer 22 uses the recognized reference mark Ref to set the transfer target position AP to which the needle 18 is to be transferred. The transfer target position AP is, for example, a position close to a first side of the sample piece Q, in which the first side is the opposite side of the support Qa. The computer 22 maps the transfer target position AP on the processing range F with a predetermined positional relationship during the formation of the sample piece Q. The computer 22 stores information on the relative positions of the processing range F and the reference mark Ref when forming a sample piece Q on the sample S by irradiating the sample S with a focused ion beam. With the use of the recognized reference mark Ref, the computer 22 moves the tip position of the needle 18 toward the transfer target position AP in 3D space using the relative positional relationship among the reference mark Ref, the processing range F, and the transfer target position AP (see FIG. 2).

In the process described above, the computer 22 may move the tip position of the needle 18 in 3D space toward the transfer target position AP using the relative positional relationship between the reference mark Ref and the transfer target position AP, without using the processing range F.

The computer 22 then executes a needle transferring operation (fine adjustment) in which the needle drive mechanism 19 moves the needle 18 (step S100). The computer 22 repeats pattern matching using the template created in step S050 and using the needle tip coordinates obtained in step S047 and moves the needle 18 in 3D space from the transfer target position AP to a connection processing position by using the needle tip coordinates obtained as the tip position of the needle 18 in the SEM image in step S047 in a state in which the irradiation region including the transfer target position AP is irradiated with a charged particle beam.

Next, the computer 22 performs the processing of stopping the movement of the needle 18 (step S110).

FIG. 10 is a view illustrating the positional relationship when the needle 18 is connected to the sample piece Q and is an enlarged view of an end of the sample piece Q. In FIG. 10, the end (cross section) of the sample piece Q to which the needle 18 is to be connected is placed at the center 35 of the SIM image, and a point spaced by a predetermined distance L1 from the SIM image center 35, i.e., the midpoint of the width of the sample piece Q, is set as the connection processing position 36. The connection processing position may be set to a point on an extension (reference numeral 36a in FIG. 10) from the end face of the sample piece Q. The computer 22 sets the upper limit of the predetermined distance L1 to 1 μm. The three-dimensional coordinates of the connection processing position 36 are stored in the computer 22.

Based on the three-dimensional coordinates of the tip of the needle 18 and the connection processing position 36 in the same SIM or SEM image, the computer 22 operates the needle drive mechanism 19 to move the needle 18 to a specified connection processing position 36. The computer 22 stops the operation of the needle drive mechanism 19 when the needle tip is positioned at the connection processing position 36.

FIG. 11 is a view schematically illustrating an example of a positional relationship between the needle 18 and the sample piece Q depending on the size of the carbon deposition film DM attached to the needle tip. Referring to FIG. 11, the distance between the tip C of the carbon deposition film DM and the sample piece Q is set to a predetermined distance L1, regardless of the size of the carbon deposition film DM. As the size of the carbon deposition film DM attached to the tip of the needle 18 increases, the tip C of the needle 18 (i.e., the tip C of the residue of the carbon deposition film DM attached to the tip of the needle 18) protrudes outward further from the body of the needle 18, and the end of the body of the needle 18 body is distanced from the sample piece Q.

Next, the computer 22 performs the processing of connecting the needle 18 to the sample piece Q (step S120). The computer 22 applies a focused ion beam to the irradiation region including the processing range set at the connection processing position 36 while the gas supply unit 17 supplies carbon-based gas, which is a gas for deposition, to the sample piece Q and the tip surface of the needle 18 for a predetermined deposition time. The computer 22 then connects the sample piece Q and the needle 18 by means of a deposition film.

In step S120, the computer 22 does not allow the needle 18 to be in direct connection with the sample piece Q but the needle 18 is connected to the sample piece Q via the deposition film formed therebetween. The needle 18 approaches and stops at a position (connection processing position) distanced by a predetermined distance L1 from the sample piece Q. The needle 18, the sample piece Q, and the deposition film formation area (for example, processing range) are set such that the deposition film formation area is bridged between the needle 18 and the sample piece Q. The deposition film is formed in the gap corresponding to the predetermined distance L1, and the needle 18 and the sample piece Q are connected by the deposition film.

The computer 22 may determine the state of connection by the deposition film by detecting changes in the absorption current of the needle 18. The computer 22 may determine that the sample piece Q and the needle 18 are connected by the deposition film when the absorption current of the needle 18 reaches a predetermined current value, and may stop the formation of the deposition film regardless of whether or not the predetermined deposition time has passed.

Next, the computer 22 performs the processing of cutting the support Qa disposed between the sample piece Q and the sample S (step S130). The computer 22 specifies a preset cutting processing position of the support Qa using the reference mark Ref formed on the sample S.

The computer 22 separates the sample piece Q from the sample S by applying a focused ion beam to the cut processing position for a predetermined cut process time.

The computer 22 determines whether the sample piece Q is separated from the sample S by detecting conduction between the sample S and the needle 18 (step S133).

When the conduction between the sample S and the needle 18 is not detected, the computer 22 determines that the sample piece Q is separated from the sample S (OK) and continues to execute the subsequent processes (i.e., the processes subsequent to step S140). On the other hand, when the conduction between the sample S and the needle 18 is detected after the completion of the cutting of the support Qa between the sample piece Q and the sample S at the cutting processing position when the cutting processing is performed, the computer 22 may determine that the sample piece Q is not separated from the sample S (NG). When the computer 22 determines that the sample piece Q is not separated from the sample S (NG), the effect that the sample piece Q has not been separated from the sample S is notified either by display on the display unit 21 or by alarming sound (step S136). The execution of the subsequent processing is then stopped. In this case, the computer 22 may cut the deposition film connecting the sample piece Q and the needle 18 (deposition film DM2 described below) by focused ion beam irradiation, separate the sample piece Q and the needle 18, and return the needle 18 to the initial position (step S030). Alternatively, needle trimming described below may be performed on the needle 18, and then the trimmed needle 18 may be returned to the initial position (step S030). After returning to the initial position, the needle 18 performs sampling of the next sample piece Q.

Next, the computer 22 performs the processing of retreating the needle 18 (step S140). The computer 22 operates the needle drive mechanism 19 to raise the needle 18 vertically upward (i.e., in the positive direction in the Z direction) by a predetermined distance (for example, 5 μm).

Next, the computer 22 performs the processing of retreating the state (step S150). The computer 22 operates the stage drive mechanism 13 to move the stage 12 by a predetermined distance.

The computer 22 operates the stage drive mechanism 13 so that no structure is present in the background of the needle 18 and sample piece Q connected to each other. The computer 22 moves the stage 12 by a predetermined distance. The state of the background of the sample piece Q is determined (step S160). When the background is determined to have no problem, the next step S170 is performed. Conversely, when the background is determined to have a problem, the stage 12 is moved again by a predetermined amount (step S165), and then the process returns to the determination of the state of the background (step S160). The determination is made until there is no problem in the background.

Next, the computer 22 executes the processing of creating a template for the needle 18 and the sample piece Q (step S170). The computer 22 creates a template of the needle 18 and sample piece Q in the posture state in which the needle 18 to which the sample piece Q fixed is rotated as necessary (that is, the posture in which the sample piece Q is connected to the columnar section 34 of the sample stand 33). This allows the computer 22 to three-dimensionally recognize the edges (contours) of the needle 18 and sample piece Q from the image data obtained by using each of the focused ion and electron beams according to the rotation of the needle 18.

In the template creation process (step S170), the computer 22 first obtains a template for template matching (reference image data) for the sample piece Q and the tip shape of the needle 18 to which the sample piece Q is connected. The computer 22 stores image data acquired from two different directions by focused ion beam irradiation and electron beam irradiation as templates (reference image data).

Next, the computer 22 performs the processing of retreating the needle (step S180). The computer 22 operates the needle drive mechanism 19 to move the needle 18 by a predetermined distance.

Next, the computer 22 operates the stage drive mechanism 13 to move the stage 12 so that a specific sample piece holder P registered in step S020 enters the observation field of view of the charged particle beam (S190). FIGS. 12 and 13 illustrate this operation. Specifically, FIG. 12 is a schematic view illustrating an image obtained by using a focused ion beam of the charged particle beam device 10 according to the embodiment of the invention, and is a view illustrating a sample piece attachment position U of a columnar section 34. FIG. 13 is a schematic view of an image obtained by using an electron beam and is a view illustrating a sample piece attachment position U of a columnar section 34.

Here, it is determined whether or not the columnar section 34 of the desired sample piece holder P falls within the observation field of view (step S195), and when the desired columnar section 34 falls within the observation field of view, the process proceeds to the next step S200. When the desired columnar section 34 does not fall within the observation field of view, that is, when the stage is not correctly driven with respect to the specified coordinates, the stage coordinates specified immediately before are initialized, and the stage 12 returns to the origin position possessed by the stage (step S197). Next, the pre-registered coordinates of the desired columnar section 34 are specified, and the stage 12 is driven (step S190). This operation is repeated until the columnar section 34 enters the observation field of view.

Next, the computer 22 drives the stage drive mechanism 13 to move the sage 12 so that the horizontal position of the sample piece holder P is adjusted and to rotate and tilt the stage 12 by a predetermined angle according to the posture control mode so that the sample piece holder P can be oriented in a predetermined posture (step S200).

Here, it is determined whether the shape of the columnar section 34 of the sample piece holder P is good or bad (step S205). Although the image of the columnar sections 34 is registered in step S023, it is determined whether the shape of the columnar section 34 is good or bad to determine whether a specified columnar section 34 is deformed, damaged, missing, etc. due to unexpected contact, etc. in the subsequent process. When the shape of the columnar section 34 is determined to be good in step S205, the process proceeds to the next step S210. When the shape is determined to be bad, the process returns to step S190 in which the stage is moved so that the next columnar section 34 enters the observation field of view.

When the computer 22 instructs the stage drive mechanism 13 to move the stage 12 so that a particular columnar section 34 enters the observation field of view, when the particular columnar section 34 does not actually enter the observation field of view, the computer 22 initializes the position coordinates of the stage 12 and moves the stage 12 to the initial position. Next, the computer 22 then moves the nozzle 17a of the gas supply unit 17 to be positioned near the focused ion beam irradiation position.

### Sample Piece Mounting Process

The term “sample piece mounting process” here refers to the process of transferring an extracted sample piece Q to a sample piece holder P.

FIG. 14 is a flowchart illustrating the flow of the process of mounting (transferring) a sample piece Q to a predetermined columnar section 34 of a predetermined sample piece holder P, the process being involved in the automatic sampling operation performed by the charged particle beam device 10 according to the embodiment of the present invention.

The computer 22 uses image data obtained by focused ion beam irradiation and electron beam irradiation to recognize the transfer position of the sample piece Q, which is stored in step S020 (step S210). The computer 22 performs template matching to confirm that the columnar section 34 that appears in the observation field of view, among the plurality of columnar sections 34 on the comb-shaped sample base 33, is a pre-specified columnar section 34. The computer 22 performs template matching with each piece of the image data obtained by focused ion beam irradiation and electron beam irradiation, using the templates for the respective columnar sections 34, which are created in the process (step S020) of creating templates for the columnar sections.

In addition, in the template matching for each columnar section 34, which is performed after moving the stage 12, the computer 22 determines whether or not a problem such as a missing columnar section 34 is recognized (step S215). When a problem is found in the shape of the columnar section 34 (NG), the columnar section 34 to which the sample piece Q is to be transferred is changed to a columnar section 34 adjacent to the columnar section 34 in which the problem was found, and template matching is also performed on that columnar section 34 to determine the columnar section 34 to which the sample piece Q is to be transferred. When there is no problem with the shape of the columnar section 34, the process proceeds to the next step S220.

The computer 22 operates the stage drive mechanism 13 to move the stage 12 so that the mounting position recognized by the electron beam irradiation matches the mounting position recognized by the focused ion beam irradiation. The computer 22 operates the stage drive mechanism 13 to move the stage 12 so that the mounting position U of the sample piece Q coincides with the center (processing position) of the field of view.

Next, the computer 22 performs the processing of steps S220 through S250 as the processing of brining the sample piece Q connected to the needle 18 into contact with the sample piece holder P.

First, the computer 22 recognizes the position of the needle 18 (step S220). The computer detects the absorption current which is a current flowing through the needle 18 when the needle 18 is irradiated with a charged particle beam, and generates absorption current image data. The computer 22 detects the tip position of the needle 18 in 3D space by using each piece of the absorption current image data obtained from two different directions by focused ion beam irradiation and electron beam irradiation. The computer 22 may use the detected tip position of the needle 18 to drive the stage 12 by using the stage drive mechanism 13, thereby setting the tip position of the needle 18 to the center position (center of field of view) of the field of view that is preset.

Next, the computer 22 executes a sample mounting process. First, the computer 22 executes needle movement in which the needle drive mechanism 19 moves the needle 18 (S230). The computer 22 measures the distance between the sample piece Q and the columnar section 34 based on template matching using the templates of the needle 18 and sample piece Q and the template of the columnar section 34 in each piece of the image data obtained by the focused ion beam irradiation and the electron beam irradiation. The computer 22 moves the needle 18 in 3D space toward the mounting position of the sample piece Q according to the measured distance.

Next, the computer 22 stops the movement of the needle 18 with a predetermined gap L2 between the columnar section 34 and the sample piece Q (step S240). The computer 22 sets the gap L2 to less than 1 μm.

In addition, when providing the gap L2, the computer 22 may provide the gap between the columnar section 34 and the needle 18 by detecting the absorption current images of the columnar section 34 and needle 18.

The computer 22 detects the presence or absence of disconnection between the sample piece Q and the needle 18 after transferring the sample piece Q to the columnar section 34 by detecting conduction between the columnar section 34 and the needle 18 or the absorption current images of the columnar section 34 and needle 18.

When the computer 22 cannot detect conduction between the columnar section 34 and the needle 18, the computer 22 switches the process to detect the absorption current images of the columnar 34 and needle 18.

When the computer 22 cannot detect conduction between the columnar section 34 and the needle 18, the computer 22 may stop the transfer of the sample piece Q, detach the sample piece Q from the needle 18, and perform a needle trimming process described below.

Next, the computer 22 performs the processing of connecting the sample piece Q connected to the needle 18 to the columnar section 34 (step S250). FIGS. 15 and 16 are schematic views of images with increased magnification, corresponding to FIGS. 12 and 13, respectively. When the needle drive mechanism 19 moves the needle such that one side of the sample piece Q and one side of the columnar section 34 are aligned as shown in FIG. 15 and that the upper end face of the sample piece Q is flush with the upper end face of the columnar section 34 as shown in FIG. 16, and the gap L2 has a predetermined value, the computer 22 stops the operation of the needle drive mechanism 19. The computer 22 sets a deposition processing range R2 to include the edge of the columnar section 34 in the image obtained by the focused ion beam irradiation as in FIG. 15 in a state in which the sample piece Q stays at the mounting position with the gap L2. The computer 22 causes the gas supply unit 17 to supply gas to the surface of the sample piece Q and the surface of the columnar section 34 and applies a focused ion beam to the irradiation region including the processing range R2 for a predetermined deposition time. This operation forms a deposition film on the focused ion beam irradiation region, thereby filling the gap L2 and connecting the sample piece Q to the columnar section 34. In the process of fixing the sample piece Q to the columnar section 34 by deposition, the computer 22 terminates the deposition when the conduction between the columnar section 34 and the needle 18 is detected.

The computer 22 determines whether the connection between the sample piece Q and the columnar section 34 is completed (step S255). For example, it is determined that the electrical connection is made by confirming that the electrical resistance between the needle 18 and the stage 12 is equal to or less than a predetermined resistance value. In addition, from preliminary studies, it is determined that when the resistance value between the two reaches a predetermined resistance value, the deposition film has sufficient mechanical strength, and the sample piece Q is sufficiently connected to the columnar part 34.

In addition, what is detected is not limited to the electrical resistance described above, and it may be electrical characteristics between the columnar section and the sample piece Q, such as current and voltage. When the predetermined electrical characteristics (electrical resistance, value of current, potential, etc.) measured within a predetermined time are not satisfied, the computer 22 may extend the deposition film formation time. The computer 22 stops gas supply and focused ion beam irradiation when the connection between the sample piece Q and the columnar section 34 is confirmed. FIG. 17 shows this state, and is a view illustrating a deposition film DM1 that connects the sample piece Q connected to the needle 18 to the columnar section 34 in image data obtained by a focused ion beam of the charged particle beam device 10 according to the embodiment of the present invention.

In addition, in step S255, the computer 22 may determine the state of connection by the deposition film DM1 by detecting changes in the absorption current of the needle 18.

When it is determined that the sample piece Q and the columnar section 34 are connected by the deposition film DM1 on the basis of the absorption current of the needle 18, the computer 22 may stop the formation of the deposition film DM1, regardless of whether or not the predetermined deposition time has passed. When the completion of the connection is confirmed, the process proceeds to the next step S260. When the connection is not completed, the focused ion beam irradiation and the gas supply are stopped at a predetermined time, the deposition film DM2 connecting the sample piece Q and the needle 18 is cut by a focused ion beam, and the sample piece Q at the needle tip is discarded. The process proceeds to the operation of retreating the needle (step S270).

Next, the computer 22 performs the processing of cutting the deposition film DM2 connecting the needle 18 and the sample piece Q and of separating the sample piece Q and the needle 18 from each other (step S260). The computer 22 separates the sample piece Q and the needle 18 from each other according to the ON and OFF of the tip processing flag according to the results of the determination in step S032 shown in FIG. 5.

FIG. 17 illustrates the behavior at the OFF state of the tip processing flag and is a view illustrating a cut processing position T2 for cutting the deposition film DM2 that connects the needle 18 to the sample piece Q, in image data obtained by using a focused ion beam of the charged particle beam device 10 according to the embodiment of the present invention. The computer 22 sets, as the cutting processing position T2, the position that is at a distance corresponding to the sum (L+L1/2) of a predetermined distance L from the side of the columnar section 34 and a half of a predetermined size L1 (see FIG. 17) of the gap between the needle 18 and the sample piece Q, in which the predetermined distance L means the sum of the gap size L2 from the side surface of the columnar section 34 to the sample piece Q and the size L3 of the sample piece Q. In addition, the cutting processing position T2 may be set at a distance of L+L1, which is the sum of the predetermined distance L and the predetermined size L1 of the gap between the needle 18 and the sample piece Q.

The computer 22 cuts only the deposition film M2 by applying a focused ion beam to the cutting processing position T2 for a predetermined time, thereby separating the needle 18 from the sample piece Q while preventing the needle 18 from being cut. FIG. 18 shows this state, and is a view illustrating a state in which the needle 18 is separated from the sample piece Q in the image data of the focused ion beam in the charged particle beam device 10 according to the embodiment of the present invention. A residue of the deposition film DM2 is attached to the needle tip.

The computer 22 determines whether the needle 18 is separated from the sample piece Q by detecting conduction between the sample piece holder P and the needle 18 (step S265). When conduction between the sample piece holder P and the needle 18 is detected after the completion of the cutting processing, i.e., after the deposition film DM2 between the needle 18 and the sample piece Q at the cutting processing position T2 is irradiated with a focused ion beam to cut the deposition film DM2, the computer 22 determines that the needle 18 is not separated from the sample stand 33. When it is determined that the needle 18 is not separated from the sample piece holder P, the computer 22 may notify the operator of the fact that the separation of the needle 18 and the sample piece Q is not completed either by displaying on the display unit 21 or by making alarming sound. The execution of the subsequent processing is then stopped. On the other hand, when the conduction between the sample piece holder P and the needle 18 is not detected, the computer 22 determines that the needle 18 is separated from the sample piece Q and continues to execute the subsequent processing.

FIG. 19 illustrates the behavior in the ON state of the tip processing flag and is a view illustrating a cutting processing region T3 for cutting the deposition film DM2 that connects the needle 18 to the sample piece Q, in image data obtained by using a focused ion beam of the charged particle beam device 10 according to the embodiment of the present invention. The computer 22 sets the cutting processing region T3 such that the total amount of changes in coordinate data becomes less than a predetermined threshold, for example, by removing at least part of a deposit such as the deposition film DM2 accumulated on the end of the body of the needle 18 according to the total amount of changes in coordinate data obtained in step S034 shown in FIG. 5. For example, the cutting processing region T3 is set such that the needle-side end of the cutting processing region T3 is located at a first distance from the side surface of the columnar section 34. The first distance is the total amount of changes in coordinate data plus the predetermined distance L+L1 (see FIGS. 11 and 17).

FIG. 20 is a view illustrating a tip portion of the needle 18 before and after the needle tip is processed with a focused ion beam of the charged particle beam device 10. The focused ion beam is applied to the cutting processing region T3 shown in FIG. 19 to remove an attachment on the tip of the needle 18 in the cutting processing region T3, so that a new tip C of the needle 18 is formed as shown in FIG. 20. For example, in the needle 18 shown in FIG. 20, an area corresponding to a predetermined length La in an axial direction AX from the tip C before the predetermined tip processing is performed is removed by the focused ion beam to form the new tip C. The predetermined length La corresponds to the coordinate difference, before and after the tip processing, in the axial direction AX in the coordinate data of the needle drive mechanism 19 when the tip C of the needle 18 is disposed at the predetermined position.

The computer 22 switches the tip processing flag from ON to OFF after performing the predetermined tip processing on the tip of the needle 18.

Next, the computer 22 performs the processing of retreating the needle (step S270). The computer 22 operates the needle drive mechanism 19 to move the needle 18 by a predetermined distance from the sample piece Q. FIGS. 21 and 22 illustrate this operation. Specifically, FIG. 21 is a schematic view illustrating an image obtained by using a focused ion beam of the charged particle beam device 10 according to the embodiment of the invention, and FIG. 22 is a schematic view illustrating an image obtained by using an electron beam, for a state in which the needle 18 is retreated in an upward direction from the sample piece Q.

Next, the computer 22 performs the processing of retreating the state (step S280). This step S280 is an operation of retreating the stage 12 from a needle sharpening position and is performed prior to a needle sharpening process to prevent spattering particles generated when a focused ion beam irradiates the needle 18 during the needle sharpening from adhering to the sample S, or to prevent the focused ion beam passing around the needle 18 from irradiating the sample S and causing damage to valuable samples S. In addition, the step is also performed to ensure matching of the needle image to the template.

### Needle Trimming Process

FIG. 23 is a flowchart illustrating the flow of the process of trimming the needle 18 during the automatic sampling operation of the charged particle beam device 10 according to the embodiment of the present invention.

The needle trimming is the shaping of the needle 18 separated from the sample piece Q into a needle shape before sampling. The needle trimming includes the removal of the deposition film DM2 and other adhesions formed on the needle tip in the previous step S260, and the shaping and sharpening of the deformed needle 18.

First, the state of the needle shape is determined (step S285). When it is determined that the deformation or damage is too severe to be regenerated by the subsequent sharpening process, the needle 18 is returned to the default setting position (step S300) and the needle 18 is replaced with a new needle 18 by the equipment operator.

The computer 22 sharpens the needle 18 by operating the needle drive mechanism 19 and the focused ion beam irradiation optics 14 and using the image data generated by focused ion beam irradiation and the image data generated by electron beam irradiation (step S290).

Prior to the sharpening (step S290) of the needle 18, the computer 22 uses the image data (reference image) of the needle obtained in step S050 or the contour lines of the needle 18 extracted from the reference image as templates.

Based on the created template, the computer 22 determines a processing range 40 within which the tip shape of the needle 18 becomes a predetermined ideal predetermined shape, and performs the trimming processing along the processing range 40. FIG. 24 is a schematic view of image data obtained by a focused ion beam of the charged particle beam device 10 according to the embodiment of the present invention and illustrates the tip shape of the needle 18 and the deposition film DM2 attached to the needle tip. FIG. 25 shows a state in which the processing range 40 is superimposed on the template obtained from the contour of the needle 18 based on the image data of the needle 18 obtained in step S080, which is the template shown in FIG. 24. The processing range 40 is an ideal tip C obtained by linearly approximating, for example, the area from the tip to the base of the needle 18.

In step S290, the computer 22 rotates the needle 18 around the central axis by a predetermined angle by using the rotation mechanism of the needle drive mechanism 19 and performs trimming processing at several different specific rotated positions. The computer 22 elliptically approximates the eccentric trajectory of the needle 18 using the position of the needle 18 at at least three different angles when the needle 18 is rotated around the central axis thereof by the rotation mechanism of the needle drive mechanism 19 (not illustrated). The computer 22 can correct the misalignment of the needle 18 at each predetermined angle by using the eccentric trajectory of the needle 18.

Since eccentricity compensation is also performed in the trimming process described above, the misalignment of the needle 18 is corrected for each rotation angle, and trimming can always be performed at the same position in the field of view.

Next, the computer 22 determines that as the deposition film DM2 is removed, the processed tip coincides with the tip position C of the template and has a predetermined shape (step S292). When the deposition film DM2 at the tip is removed and the processed tip coincides with the tip position C of the template, the trimming process is determined to be finished (OK), and the process proceeds to the next step SS298. When the processed needle tip shape is defective (NG), the processing range 40 is translated in the direction of the root of the needle 18 by a predetermined dimension, for example, an integer multiple of the needle diameter (step S293), and steps S290 and S292 are performed again. This work is repeated until the processed tip reaches the tip position C. When the predetermined shape is obtained, the trimming processing is stopped, and the process proceeds to the next step S298.

Next, it is determined whether to continue sampling from a different location of the same sample S (step S298). Since the settings of the number of pieces to be sampled is registered in advance in step S010, the computer 22 checks this data to determine the next step. When sampling is to be continued, step S030 and the subsequent steps are performed as the sampling operation. When sampling is not to be continued, the process proceeds to the next step S300.

Next, the computer 22 then controls the needle drive mechanism 19 to move the needle 18 to the initial setting position (step S300).

The needle template creation in step S050 may be performed immediately after step S298. This simplifies the process by eliminating the need to perform step S050 in the next sampling as a step for preparing the next sampling.

With the step, the series of automatic sampling operations are finished.

The flow from the start to the end is only one example, and the steps in the flow may be replaced or may be skipped if the replacing or skipping does not affect the overall flow.

The computer 22 enables unattended sampling operations by continuously executing the steps, from the start to the end.

As described above, since the charged particle beam device 10 according to one embodiment of the present invention is equipped with the computer 22 that executes predetermined tip processing when the total amount of change in coordinate data of the needle drive mechanism 19, which is acquired when the apparent tip of the needle 18 coincides with a predetermined position, a to or greater than predetermined threshold, a predetermined tip shape of the needle 18 can be maintained. This allows the sampling operation in which the sample piece Q formed by processing the sample S with a focused ion beam is picked out and transferred to the sample piece holder P, to be performed automatically and continuously.

Furthermore, the computer 22 sets the cutting process region T3 according to the total change in coordinate data when separating the sample piece Q from the needle 18 as the predetermined tip processing, and irradiates the cutting processing region T3 with a focused ion beam, so that a more efficient sampling operation can be performed than the case where a special process only for processing the tip of the needle 18 is provided.

Furthermore, since the computer 22 reduces the total change in the coordinate data at least from the tip of the needle 18 in an axially outward direction to be less than a predetermined threshold by performing the predetermined tip processing, it is possible to drive the needle 18 in 3D space properly (i.e., without contact with other components or devices) when connecting the needle 18 and the sample piece Q to each other.

### Modification

Hereinafter, a modification to the embodiment will be described.

In the embodiment described above, the computer 22 acquires the coordinate data of the needle drive mechanism 19 (step S302) in a state in which the tip of the needle 18 coincides with a predetermined position when the needle 18 is moved to the initial setting position (step S030), but the present invention is not limited thereto. The computer 22 may acquire the coordinate data of the needle drive mechanism 19 at other times, for example, at an appropriate time at which the tip of the needle 18 coincides with a predetermined position when the needle 18 is moved by the needle drive mechanism 19.

In the embodiment described above, the computer 22 cuts the deposition film DM2 connecting the needle 18 and the sample piece Q to each other by a cutting processing region T3 that is set according to the total change in coordinate data when the tip processing flag is set to ON. However, the present invention is not limited thereto. The computer 22 can also set the position of the cutting process region T3 according to the total change in coordinate data, not depending on the tip processing flag being set to ON or OFF. The computer 22 may also perform predetermined tip processing so that the total change in coordinate data becomes less than a predetermined threshold at other appropriate times, such as timing at which needle sharpening is performed by a needle trimming process (step S290).

For example, the computer 22 may provide timing at which only the tip processing of the needle 18 is performed, as one of timings other than the timing for separating the needle 18 from the sample piece Q. In this case, the computer 22 may, for example, trim the tip of the needle 18 by an amount equal to the total change in coordinate data.

In the embodiment described above, the needle drive mechanism 19 may be integrated with the stage 12, but the present invention is not limited thereto. The needle drive mechanism 19 and the stage 12 may be provided as separate members. The needle drive mechanism 19 may be independent of the tilt drive of the stage 12, and may be, for example, fixed to the sample chamber 11.

In the embodiment described above, the focused ion beam irradiation optics 14 is configured such that the optical axis thereof is parallel to the vertical direction, and the electron beam irradiation optics 15 is configured such that the optical axis thereof is inclined with respect to the vertical direction. However, the present invention is not limited thereto. For example, the focused ion beam irradiation optics 14 may be configured such that the optical axis thereof is inclined with respect to the vertical direction, and the electron beam irradiation optics 15 may be configured such that the optical axis there is parallel to the vertical direction.

In the embodiment described above, the charged particle beam irradiation optics is configured to emit two types of beams by being equipped with a focused ion beam irradiation optics 14 and an electron beam irradiation optics 15, but is not limited to thereto. For example, the configuration may not include an electron beam irradiation optics 15 and include only a focused ion beam irradiation optics 14 installed in the vertical direction.

In the above-mentioned embodiment, in some of the above-described steps, the sample piece holder P, the needle 18, the sample piece Q, etc. are irradiated with an electron beam and a focused ion beam from different directions to acquire an image of the electron beam and an image of the focused ion beam, and the positions of the sample piece holder P, the needle 18, the sample piece Q, etc. and the positional relationships thereof are identified from the images. However, the device may include only the focused ion beam irradiation optics 14, and the sample piece Q may be observed with focused ion beams applied from two different directions.

In the embodiment described above, the computer 22 automatically executes the series of steps S010 to S300 as an automatic sampling operation, but the present invention is not limited thereto. The computer 22 may switch to perform at least any one of steps S010 through S300 by manual operation of the operator.

In the embodiment described above, template matching may be used to recognize the tip of the needle 18 in each of the SIM and SEM images, or artificial intelligence (AI) recognition may be used without using templates.

The embodiments of the invention are presented for illustrative purposes and are not intended to limit the scope of the invention. These embodiments can be implemented in various other forms, and various omissions, substitutions, and changes can be made without departing from the gist of the invention. These embodiments and modifications thereto fall within the scope and idea of the inventions and also fall within the scopes of the inventions defined in the claims and their equivalents.

### EXPLANATION OF REFERENCE NUMERALS

10 . . . Charged particle beam device, 11 . . . Sample chamber, 12 . . . Stage (sample stage), 12a . . . Holder securing stand, 13 . . . Stage drive mechanism, 14 . . . Focused ion beam irradiation optics (charged particle beam irradiation optics), 15 . . . Electron beam irradiation optics (Charged particle beam irradiation optics), 16 . . . Detector, 17 . . . Gas supply unit, 18 . . . Needle (Sample piece transfer means), 19 . . . Needle drive mechanism (specimen transfer means), 20 . . . Absorption current detector, 21 . . . Display device, 22 . . . Computer, 23 . . . Input device, 33 . . . Sample stand, 34 . . . Columnar section, AX . . . Axial direction, P . . . Sample piece holder, Q . . . Sample piece, R . . . Secondary charged particle, S . . . Sample, T3 . . . Processing area.

1. A charged particle beam device that automatically produces a sample piece from a sample, the charged particle beam device comprising:
a charged particle beam irradiation optical system applying a charged particle beam;
a sample stage on which a sample is loaded and moved;
a sample piece transfer means for holding and transporting a sample piece to be separated and extracted from the sample;
a holder securing stand holding the sample piece holder to which the sample piece is transferred;
a gas supply unit supplying gas to form a deposition film by irradiation with the charged particle beam; and
a computer storing coordinate data indicating a real-space position of the sample piece transfer means in case a tip of the sample piece transfer means is present within a predetermined tolerance range from a predetermined position in an image obtained by irradiating the sample piece transfer means with the charged particle beam in a state in which the sample piece is not held and controlling the sample piece transfer means and the charged particle beam irradiation optical system to carry out processing to remove at least part of the deposition film attached to the tip of the sample piece transfer means by irradiation with the charged particle beam in case an amount of change in the coordinate data for a suitable period of time is equal to or greater than a predetermined threshold value,
wherein, when separating the sample piece from the sample piece transfer means that holds the sample piece, the computer sets a processing area according to an amount of change in the coordinate data in the image obtained by irradiation with the charged particle beam and removes at least part of the deposition film attached to the tip of the sample piece transfer means by irradiating the processing area with the charged particle beam.

2. (canceled)

3. The charged particle beam device according to claim 1, wherein the computer carries out the processing so that the amount of change in the coordinate data from at least the tip of the sample piece transfer means in an axially outward direction parallel to a central axis of the sample piece transfer means becomes less than the predetermined threshold value.

4. The charged particle beam device according to claim 3, wherein, in case an amount of change in the coordinate data is less than the predetermined threshold, the computer sets a tip processing flag to OFF and, in case the amount of change in coordinate data is equal to or greater than the predetermined threshold value, the computer sets the tip processing flag to ON and
wherein, when separating the sample piece from the sample piece transfer means, where L means a sum of a distance from a side surface of a columnar section of the sample piece holder to which the sample piece is transferred to the sample piece and a size of the sample piece and L1 means a distance from the sample piece transfer means to the sample piece,
in case the tip processing flag is set to OFF, the computer sets a position that is at a distance corresponding to L+L1 from the side surface of the columnar section as a cutting processing position for cutting the deposition film that connects the sample piece transfer means to the sample piece,
in case the tip processing flag is set to ON, the computer sets the processing area so that an end at the sample piece transfer means-side of the processing area is placed at a first distance that is greater than L+L1 from the side surface of the columnar section, and the first distance is a distance where an amount of change in the coordinate data becomes less than a predetermined threshold value.
